(19) United States
(12) Patent Application Publication
(10) Pub. No.: US 2023/0272155 A1
(43) Pub. Date: Aug. 31, 2023

(54) PHENOL RESIN, EPOXY RESIN, METHODS FOR PRODUCING THESE, EPOXY RESIN COMPOSITION AND CURED PRODUCT THEREOF

(71) Applicants: NIPPON STEEL Chemical & Material Co., Ltd., Tokyo (JP); KUKDO CHEMICAL CO., LTD., Seoul (KR)

(72) Inventors: Masahiro SOH, Tokyo (JP); Kazuo ISHIHARA, Tokyo (JP); KIHWAN YU, Seoul (KR); CHEONGRAE LIM, Seoul (KR); JOONGHWI JEE, Seoul (KR)

(73) Assignees: NIPPON STEEL Chemical & Material Co., Ltd., Tokyo (JP); KUKDO CHEMICAL CO., LTD., Seoul (KR)

(21) Appl. No.: 18/008,666

(22) PCT Filed: Jun. 4, 2021
(86) PCT No.: PCT/JP2021/021361

§ 371 Date: Dec. 7, 2022

(30) Foreign Application Priority Data
Jun. 11, 2020 (JP) 2020-101469

(51) Int. Cl. C08G 59/62; C08G 8/20; C08J 5/24; H05K 1/03; B32B 5/02

(52) U.S. Cl. CPC C08G 59/621; B32B 5/02; C08G 8/20; C08J 5/244; H05K 1/0326; B32B 15/20; C08J 2363/00

(57) ABSTRACT

To provide an epoxy resin composition that exhibits excellent low dielectric properties and that is excellent in copper foil peel strength and interlayer cohesion strength in a printed-wiring board application, a phenol resin and an epoxy resin for providing the composition, and a method for producing such a resin. A phenol resin containing a dicyclopentenyl group and represented by the following general formula (1): wherein each R¹ independently represents a hydrocarbon group having 1 to 8 carbon atoms; each R² independently represents a hydrogen atom or a dicyclopentenyl group, and at least one R² is a dicyclopentenyl group; i is an integer of 0 to 2; and n represents the number of repetitions and an average value thereof is a number of 10 to 10.

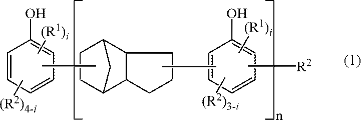

### TECHNICAL FIELD

The present invention relates to a phenol resin or an epoxy resin excellent in low dielectric properties and high adhesiveness, and a method for producing such a resin.

### BACKGROUND ART

Epoxy resins are excellent in adhesiveness, flexibility, heat resistance, chemical resistance, insulation properties and curing reactivity, and thus are used variously in paints, civil adhesion, cast molding, electrical and electronic materials, film materials, and the like. In particular, epoxy resins, to which flame retardance is imparted, are widely used in applications of printed-wiring substrates as one of electrical and electronic materials.

In recent years, information equipment has been rapidly progressively reduced in size and increased in performance, and materials for use in the fields of semiconductors and electronic components have been accordingly demanded to have higher performance than even before. In particular, epoxy resin compositions serving as materials for electrical and electronic components have been demanded to have low-dielectric properties along with thinning and functionalization of substrates.

Dicyclopentadiene phenol resins and the like having aliphatic backbones introduced, which have been heretofore used for reduction in permittivity in applications of laminated boards, are less effective for improvement in dielectric tangent and have no satisfiable adhesiveness. There have not been disclosed any resin where substitution with a plurality of dicyclopentadiene-derived dicyclopentenyl groups is made on a phenol ring (Patent Literatures 1 and 2).

### CITATION LIST

### Patent Literatures

Patent Literature 1: Japanese Patent Laid-Open No. 2001-240654
Patent Literature 2: Japanese Patent Laid-Open No. 5-339341

### SUMMARY OF INVENTION

Accordingly, a problem to be solved by the present invention is to provide a dicyclopentadiene-type phenol resin and a dicyclopentadiene-type epoxy resin that each allow a cured product exhibiting an excellent dielectric tangent and also having favorable adhesiveness to be obtained, as well as an epoxy resin composition using such a resin and a method for producing such a resin.

In order to solve the above problem, the present inventors have made studies about a method for producing a dicyclopentadiene-type phenol resin, and as a result, have found that a dicyclopentadiene-type phenol resin can further react with dicyclopentadiene at a specified ratio to thereby allow a dicyclopentadiene-derived dicyclopentenyl group to be added to a phenol ring of the dicyclopentadiene-type phenol resin and furthermore a cured product obtained by curing an epoxy resin obtained by epoxidation of the phenol resin, with a curing agent, is excellent in low dielectric properties and in adhesiveness, thereby completing the present invention.

In other words, the present invention relates to a phenol resin containing a dicyclopentenyl group and represented by the following general formula (1):

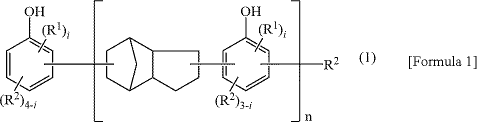

wherein each R¹ independently represents a hydrocarbon group having 1 to 8 carbon atoms; each R² independently represents a hydrogen atom or a dicyclopentenyl group, and at least one R² is a dicyclopentenyl group; i is an integer of 0 to 2; and n represents the number of repetitions and an average value thereof is a number of 0 to 10.

Preferably, R¹ is a methyl group or a phenyl group, and i is 1 or 2.

The present invention also relates to a method for producing the above dicyclopentenyl group-containing phenol resin, including: reacting 0.05 to 2.0 mol of dicyclopentadiene per mol of a phenolic hydroxyl group of a phenol resin represented by the following general formula (3) at a reaction temperature of 50 to 200° C., in the presence of a Lewis acid:

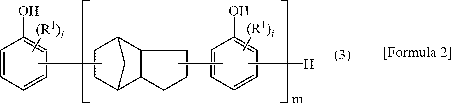

wherein R¹ and i have the same meanings as the respective definitions in the general formula (1); and m represents the number of repetitions and an average value thereof is a number of 0 to 5.

Preferably, 0.001 to 20 parts by mass of a Lewis acid based on 100 parts by mass of the dicyclopentadiene is used.

The present invention also relates to a dicyclopentenyl group-containing epoxy resin represented by the following general formula (2):

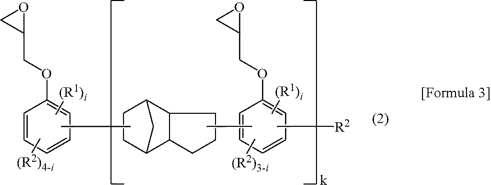

wherein R¹, R², and i have the same meanings as the respective definitions in the general formula (1); and k represents the number of repetitions and an average value thereof is a number of 0 to 10.

The present invention also relates to a method for producing the dicyclopentenyl group-containing epoxy resin, including: reacting 1 to 20 mol of epihalohydrin per mol of a phenolic hydroxyl group of the above dicyclopentenyl group-containing phenol resin, in the presence of an alkali metal hydroxide.

The present invention also relates to an epoxy resin composition including an epoxy resin and a curing agent, wherein the above dicyclopentenyl group-containing phenol resin and/or the epoxy resin are/is essential component(s) .

The present invention also relates to a cured product obtained by curing the epoxy resin composition, and a prepreg, a laminated board or a printed-wiring substrate using the epoxy resin composition.

The production method of the present invention can allow a dicyclopentadiene-derived dicyclopentenyl group to be easily added to a phenol ring of a dicyclopentadiene-type phenol resin. A cured product using a phenol resin and/or an epoxy resin obtained by the production method exhibits an excellent dielectric tangent, and furthermore an epoxy resin composition excellent in copper foil peel strength and interlayer cohesion strength in a printed-wiring board application is provided.

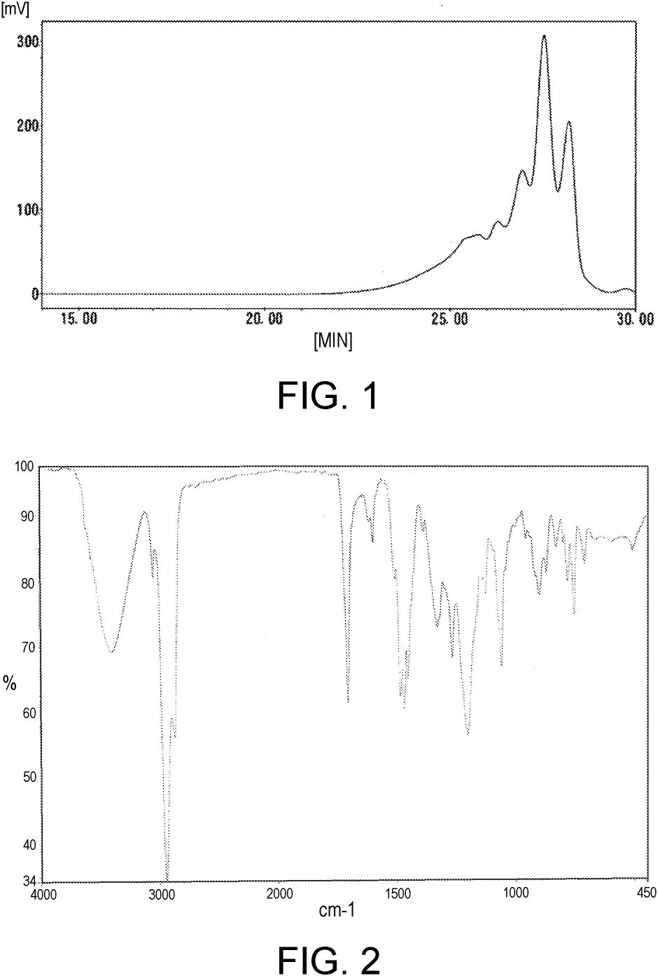

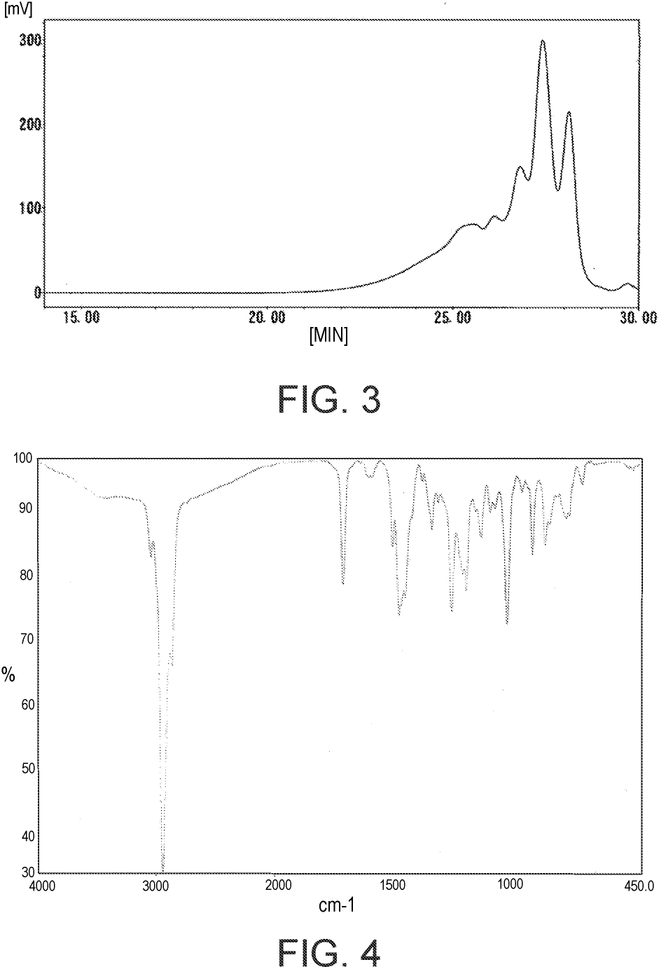

### BRIEF DESCRIPTION OF DRAWINGS

[FIG. 1] A GPC chart of a phenol resin obtained in Example 1.

[FIG. 2] An IR chart of the phenol resin obtained in Example 1.

[FIG. 3] A GPC chart of an epoxy resin obtained in Example 6.

[FIG. 4] An IR chart of the epoxy resin obtained in Example 6.

### DESCRIPTION OF EMBODIMENTS

Hereinafter, embodiments of the present invention will be described in detail.

The phenol resin of the present invention is a phenol resin containing a dicyclopentenyl group and represented by the general formula (1). The resin is obtained by, for example, reacting dicyclopentadiene with the dicyclopentadiene-type phenol resin represented by the general formula (3), in the presence of a Lewis acid.

The dicyclopentadiene-type phenol resin represented by the general formula (3) has a structure where a phenol compound is linked by dicyclopentadiene. The phenol resin represented by the general formula (1) of the present invention is the dicyclopentadiene-type phenol resin of the formula (3), in which dicyclopentadiene is further added to a phenol ring and is present as a substituent (R²) .

In the general formula (1), R¹ preferably represents a hydrocarbon group having 1 to 8 carbon atoms, an alkyl group having 1 to 8 carbon atoms, an aryl group having 6 to 8 carbon atoms, an aralkyl group having 7 to 8 carbon atoms, or an allyl group. The alkyl group having 1 to 8 carbon atoms may be any of linear, branched and cyclic groups, and examples thereof include a methyl group, an ethyl group, a propyl group, an isopropyl group, a n-butyl group, a t-butyl group, a hexyl group, a cyclohexyl group and a methylcyclohexyl group, but not limited thereto. Examples of the aryl group having 6 to 8 carbon atoms include a phenyl group, a tolyl group, a xylyl group and an ethylphenyl group, but not limited thereto. Examples of the aralkyl group having 7 to 8 carbon atoms include a benzyl group and an α-methylbenzyl group, but not limited thereto. Among these substituents, a phenyl group and a methyl group are preferable and a methyl group is particularly preferable, from the viewpoints of availability, and reactivity of a cured product obtained. The position of substitution with R¹ may be any of the ortho-position, the meta-position and the para-position, and is preferably the ortho-position.

i is the number of substituents R¹, and is 0 to 2, preferably 1 to 2.

Each R² independently represents a hydrogen atom or a dicyclopentenyl group, and at least one R² is a dicyclopentenyl group. The dicyclopentenyl group is a group derived from dicyclopentadiene, and is represented by the following formula (1a) or formula (lb). The presence of the group can allow for reductions in permittivity and dielectric tangent of a cured product of a resin composition including the phenol resin or the epoxy resin of the present invention.

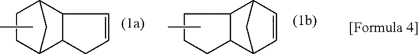

n is the number of repetitions and represents a number of 0 or more, and the average value (number average) thereof is 0 to 10, preferably 1.0 to 5.0, more preferably 1.2 to 4.0, further preferably 1.3 to 3.5.

The contents of an n = 0 form, an n = 1 form, and an n ≥ 2 form, according to GPC, are respectively in the ranges of 10% by area or less, 20 to 70% by area, and 20 to 80% by area.

The phenol resin of the present invention preferably has a weight average molecular weight (Mw) of 400 to 2000, more preferably 500 to 1500, further preferably 600 to 1400, and preferably has a number average molecular weight (Mn) of 350 to 1500, more preferably 400 to 1000, further preferably 500 to 800.

The phenolic hydroxyl group equivalent (g/eq.) is preferably 190 to 500, more preferably 220 to 500, further preferably 250 to 400.

The softening point is preferably 80 to 180° C., more preferably 90 to 160° C.

The dicyclopentadiene-type phenol resin represented by the general formula (3), serving as a raw material, is obtained by reacting a phenol compound represented by the following general formula (4) with dicyclopentadiene in the presence of a Lewis acid:

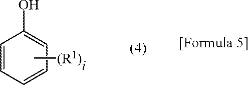

wherein R¹ and i have the same meanings as the respective definitions in the general formula (1).

In the general formula (3), R¹ and i have the same meanings as the respective definitions in the general formula (1).

m is the number of repetitions and represents a number of 0 or more, and the average value (number average) thereof is 0 to 5, preferably 1.0 to 4.0, more preferably 1.1 to 3.0, further preferably 1.2 to 2.5.

The phenolic hydroxyl group equivalent (g/eq.) in the dicyclopentadiene-type phenol resin represented by the general formula (3) is preferably 150 to 250, more preferably 160 to 220, further preferably 170 to 210.

The contents of an m = 0 form, an m = 1 form, and an m ≥ 2 form, according to GPC, are respectively in the ranges of 10% by area or less, 50 to 90% by area, and 10 to 50% by area.

Examples of the phenol compound represented by the general formula (4) include phenol, cresol, ethylphenol, propylphenol, isopropylphenol, n-butylphenol, t-butylphenol, hexylphenol, cyclohexylphenol, phenylphenol, tolylphenol, benzylphenol, α-methylbenzylphenol, allylphenol, dimethylphenol, diethylphenol, dipropylphenol, diisopropylphenol, di(n-butyl)phenol, di(t-butyl)phenol, dihexylphenol, dicyclohexylphenol, diphenylphenol, ditolylphenol, dibenzylphenol, bis (α-methylbenzyl)phenol, methylethylphenol, methylpropylphenol, methylisopropylphenol, methylbutylphenol, methyl-t-butylphenol, methyl allylphenol and tolylphenylphenol. Phenol, cresol, phenylphenol, dimethylphenol, and diphenylphenol are preferable, and cresol and dimethylphenol are particularly preferable, from the viewpoints of availability, and reactivity of a cured product obtained.

The catalyst for use in the reaction is a Lewis acid, is specifically, for example, boron trifluoride, a boron trifluoride/phenol complex, a boron trifluoride/ether complex, aluminum chloride, tin chloride, zinc chloride or iron chloride, and in particular, a boron trifluoride/ether complex is preferable in terms of ease of handling. In the case of a boron trifluoride/ether complex, the amount of the catalyst used is 0.001 to 20 parts by mass, preferably 0.5 to 10 parts by mass based on 100 parts by mass of the dicyclopentadiene.

The ratio between the phenol compound and dicyclopentadiene in the reaction, as the ratio of dicyclopentadiene per mol of the phenol compound, is 0.08 to 0.80 mol, preferably 0.09 to 0.60 mol, more preferably 0.10 to 0.50 mol, further preferably 0.11 to 0.40 mol, particularly preferably 0.11 to 0.20 mol.

The reaction is favorably made in a manner where the phenol compound and a catalyst are loaded into a reactor and dicyclopentadiene is dropped over 0.1 to 10 hours, preferably 0.5 to 8 hours, more preferably 1 to 6 hours.

The reaction temperature is preferably 50 to 200° C., more preferably 100 to 180° C., further preferably 120 to 160° C. The reaction time is preferably 1 to 10 hours, more preferably 3 to 10 hours, further preferably 4 to 8 hours.

After completion of the reaction, the catalyst is deactivated by addition of an alkali such as sodium hydroxide, potassium hydroxide, or calcium hydroxide. Thereafter, a solvent, for example, an aromatic hydrocarbon compound such as toluene or xylene or a ketone compound such as methyl ethyl ketone or methyl isobutyl ketone is added for dissolution, the resultant is washed with water, thereafter the solvent is recovered under reduced pressure, and thus the objective dicyclopentadiene phenol resin represented by the general formula (3) can be obtained. Preferably, the dicyclopentadiene is reacted in the entire amount as much as possible and the unreacted raw material phenol compound is recovered under reduced pressure.

During the reaction, a solvent, for example, an aromatic hydrocarbon compound such as benzene, toluene or xylene, a ketone compound such as methyl ethyl ketone or methyl isobutyl ketone, a halogenated hydrocarbon compound such as chlorobenzene or dichlorobenzene, or an ether compound such as ethylene glycol dimethyl ether or diethylene glycol dimethyl ether may be, if necessary, used.

The reaction method for introducing the dicyclopentenyl structure of the formula (1a) or formula (1b) into the dicyclopentadiene-type phenol resin represented by the general formula (3) is a method for reacting dicyclopentadiene with the dicyclopentadiene phenol resin at a predetermined ratio. The reaction ratio of dicyclopentadiene per mol of the phenolic hydroxyl group of the dicyclopentadiene phenol resin is 0.05 to 2.0 mol, more preferably 0.1 to 1.0 mol, further preferably 0.15 to 0.80 mol, particularly preferably 0.30 to 0.70 mol.

The catalyst for use in the reaction is a Lewis acid, is specifically, for example, boron trifluoride, a boron trifluoride/phenol complex, a boron trifluoride/ether complex, aluminum chloride, tin chloride, zinc chloride or iron chloride, and in particular, a boron trifluoride/ether complex is preferable in terms of ease of handling. In the case of a boron trifluoride/ether complex, the amount of the catalyst used is 0.001 to 20 parts by mass, preferably 0.5 to 10 parts by mass based on 100 parts by mass of dicyclopentadiene.

The reaction is favorably made in a manner where the dicyclopentadiene phenol resin, a catalyst and a solvent are loaded into a reactor and dissolved, and then dicyclopentadiene is dropped over 0.1 to 10 hours, preferably 0.5 to 8 hours, more preferably 1 to 6 hours.

The reaction temperature is preferably 50 to 200° C., more preferably 100 to 180° C., further preferably 120 to 160° C. The reaction time is preferably 1 to 10 hours, more preferably 3 to 10 hours, further preferably 4 to 8 hours.

After completion of the reaction, the catalyst is deactivated by addition of an alkali such as sodium hydroxide, potassium hydroxide, or calcium hydroxide. Thereafter, a solvent, for example, an aromatic hydrocarbon compound such as toluene or xylene or a ketone compound such as methyl ethyl ketone or methyl isobutyl ketone is added for dissolution, the resultant is washed with water, thereafter the solvent is recovered under reduced pressure, and thus an objective phenol resin can be obtained.

Examples of the solvent used in the reaction include solvents, for example, aromatic hydrocarbon compounds such as benzene, toluene and xylene, ketone compounds such as methyl ethyl ketone and methyl isobutyl ketone, halogenated hydrocarbon compounds such as chlorobenzene and dichlorobenzene, and ether compounds such as ethylene glycol dimethyl ether and diethylene glycol dimethyl ether. Such solvents may be used singly or as a mixture of two or more kinds thereof.

The method of confirming introduction of the substituent (dicyclopentenyl group) represented by the formula (1a) or formula (1b) into the phenol resin of the present invention can be made by using mass spectrometry or FT-IR measurement.

In the case of use of mass spectrometry, for example, electrospray mass spectrometry (ESI-MS) or a field desorption method (FD-MS) can be used. The introduction of the substituent represented by the formula (1a) or formula (1b) can be confirmed by subjecting a sample where components different in number of nuclei are separated in GPC or the like, to mass spectrometry.

In the case of use of a FT-IR measurement method, a KRS-5 cell is coated with a sample dissolved in an organic solvent such as THF and such a cell provided with a thin film of the sample, obtained by drying the organic solvent, is subjected to FT-IR measurement, and thus a peak assigned to C—O stretching vibration of a phenol nucleus appears around 1210 cm⁻¹ and a peak assigned to C-H stretching vibration of an olefin moiety of a dicyclopentenyl backbone appears around 3040 cm⁻¹ only in the case of introduction of the formula (1a) or formula (1b). Herein, a dicyclopentenyl group serving as a group for linking the phenol compound is not olefinic, and the absorption peak does not appear.

When one obtained by linearly connecting the start and the end of an objective peak is defined as a baseline and the length from the top of the peak to the baseline is defined as a peak height, the amount of introduction of the formula (1a) or formula (1b) can be quantitatively determined by the ratio (A₃₀₄₀/A₁₂₁₀) of the peak (A₃₀₄₀) around 3040 cm⁻¹ to the peak (A₁₂₁₀) around 1210 cm⁻¹. It can be confirmed that, as the ratio is higher, the values of physical properties are more favorable, and a preferable ratio (A₃₀₄₀/A₁₂₁₀) for satisfaction of objective physical properties is 0.05 or more, more preferably 0.10 or more, further preferably 0.15 or more. The upper limit value is not particularly limited, and is, for example, about 0.50.

The epoxy resin of the present invention is represented by the general formula (2). The epoxy resin is obtained by a reaction of epihalohydrin such as epichlorohydrin with the phenol resin represented by the general formula (1). The reaction is performed according to a conventionally known method.

In the general formula (2), R¹, R², and i have the same meanings as the respective definitions in the general formula (1).

k is the number of repetitions and represents a number of 0 or more, and the average value (number average) thereof is 0 to 10, preferably 1.0 to 5.0, more preferably 1.2 to 4.0, further preferably 1.3 to 3.5.

The epoxidation method can be made by, for example, addition of an alkali metal hydroxide such as sodium hydroxide in the form of a solid or an aqueous concentrated solution to a mixture of the phenol resin and an excess mole of epihalohydrin relative to the hydroxyl group of the phenol resin and a reaction at a reaction temperature of 30 to 120° C. for 0.5 to 10 hours, or addition of a quaternary ammonium salt such as tetraethylammonium chloride as a catalyst to the phenol resin and an excess mole of epihalohydrin, addition of an alkali metal hydroxide such as sodium hydroxide as a solid or an aqueous concentrated solution to polyhalohydrin ether obtained from a reaction at a temperature of 50 to 150° C. for 1 to 5 hours, and a reaction at a temperature of 30 to 120° C. for 1 to 10 hours.

The amount of epihalohydrin used in the reaction, relative to the hydroxyl group of the phenol resin, is 1 to 20-fold moles, preferably 2 to 8-fold moles. The amount of the alkali metal hydroxide used, relative to the hydroxyl group of the phenol resin, is 0.85 to 1.15-fold moles.

The epoxy resin obtained by such a reaction includes the unreacted epihalohydrin and alkali metal halide, thus the unreacted epihalohydrin is evaporated and removed and furthermore the alkali metal halide is removed by method(s) such as extraction with water and/or separation by filtration, from the reaction mixture, and thus an objective epoxy resin can be obtained.

The epoxy equivalent (g/eq.) of the epoxy resin of the present invention is preferably 200 to 4000, more preferably 220 to 2000, further preferably 250 to 700. In particular, when dicyandiamide is used as a curing agent, the epoxy equivalent is preferably 300 or more in order to prevent a dicyandiamide crystal from being precipitated on a prepreg.

The contents of a k = 0 form, a k = 1 form, and a k ≥ 2 form, according to GPC, are respectively in the ranges of 10% by area or less, 10 to 70% by area, and 30 to 80% by area.

The total content of chlorine is preferably 2000 ppm or less, further preferably 1500 ppm or less.

A molecular weight distribution of an epoxy resin obtained by the production method of the present invention can be changed by the change in loading ratio of the phenol resin and epihalohydrin during the epoxidation reaction, and, as the amount of epihalohydrin is closer to an equal mole to that of the hydroxyl group of the phenol resin, a higher molecular weight distribution is obtained, and, as the amount is closer to 20-fold moles, a lower molecular weight distribution is obtained. The resulting epoxy resin can also be increased in molecular weight by the action of the phenol resin again.

The epoxy resin composition of the present invention can be obtained by use of the phenol resin of the present invention and/or the epoxy resin of the present invention. The epoxy resin composition of the present invention includes the epoxy resin and a curing agent as essential components. In this aspect, the curing agent is the phenol resin of the present invention and/or the epoxy resin is the epoxy resin of the present invention.

At least 30% by mass of the curing agent preferably corresponds to the phenol resin represented by the general formula (1), or preferably at least 30% by mass, more preferably 50% by mass or more of the epoxy resin corresponds to the epoxy resin represented by the general formula (2). If the proportions are less than such values, dielectric properties may be degraded.

In other words, when 30% by mass or more of the curing agent corresponds to the phenol resin of the present invention, the epoxy resin is not required to be the epoxy resin of the present invention, and when the phenol resin of the present invention occupies less than 30% by mass of the curing agent, 30% by mass or more of the epoxy resin essentially corresponds to the epoxy resin of the present invention.

Various epoxy resins may be, if necessary, used singly or in combinations of two or more kinds thereof for the epoxy resin used for providing the epoxy resin composition of the present invention.

Any common epoxy resin having two or more epoxy groups in its molecule can be used as the epoxy resin that can be used in combination. Examples include a bisphenol A-type epoxy resin, a bisphenol F-type epoxy resin, a bisphenol AF-type epoxy resin, a tetramethyl bisphenol F-type epoxy resin, a hydroquinone-type epoxy resin, a biphenyl-type epoxy resin, a stilbene-type epoxy resin, a bisphenol fluorene-type epoxy resin, a bisphenol S-type epoxy resin, a bisthio ether-type epoxy resin, a resorcinol-type epoxy resin, a biphenyl aralkylphenol-type epoxy resin, a naphthalene diol-type epoxy resin, a phenol novolac-type epoxy resin, an aromatic modified phenol novolac-type epoxy resin, a cresol novolac-type epoxy resin, a alkyl novolac-type epoxy resin, a bisphenol novolac-type epoxy resin, a binaphthol-type epoxy resin, a naphthol novolac-type epoxy resin, a β-naphthol aralkyl-type epoxy resin, a dinaphthol aralkyl-type epoxy resin, an α-naphthol aralkyl-type epoxy resin, a trifunctional epoxy resin such as a trisphenylmethane-type epoxy resin, a tetrafunctional epoxy resin such as a tetrakisphenylethane-type epoxy resin, a dicyclopentadiene-type epoxy resin other than that in the present invention, polyhydric alcohol polyglycidyl ether such as 1,4-butane diol diglycidyl ether, 1,6-hexane diol diglycidyl ether, glycerol polyglycidyl ether, trimethylolpropane polyglycidyl ether, trimethylolethane polyglycidyl ether and pentaerythritol polyglycidyl ether, an alkylene glycol-type epoxy resin such as propylene glycol diglycidyl ether, an aliphatic cyclic epoxy resin such as cyclohexane dimethanol diglycidyl ether, a glycidyl ester compound such as dimer acid polyglycidyl ester, a glycidylamine-type epoxy resin such as phenyldiglycidylamine, tolyldiglycidylamine diaminodiphenylmethane tetraglycidylamine and an aminophenol-type epoxy resin, an alicyclic epoxy resin such as Celloxide 2021P (manufactured by Daicel Corporation), a phosphorus-containing epoxy resin, a bromine-containing epoxy resin, a urethane-modified epoxy resin, and an oxazolidone ring-containing epoxy resin, but not limited thereto. Such epoxy resins may be used singly or in combinations of two or more kinds thereof. An epoxy resin represented by the following general formula (5), a dicyclopentadiene-type epoxy resin other than that in the present invention, a naphthalene diol-type epoxy resin, a phenol novolac-type epoxy resin, an aromatic modified phenol novolac-type epoxy resin, a cresol novolac-type epoxy resin, an α-naphthol aralkyl-type epoxy resin, a dicyclopentadiene-type epoxy resin, a phosphorus-containing epoxy resin, and an oxazolidone ring-containing epoxy resin are further preferably used from the viewpoint of availability.

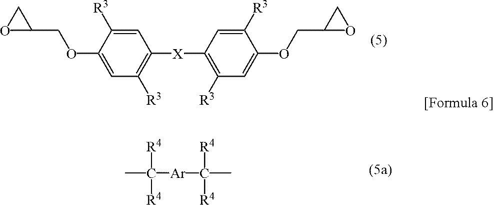

Each R³ independently represents a hydrocarbon group having 1 to 8 carbon atoms, and is, for example, an alkyl group such as a methyl group, an ethyl group, a n-propyl group, an isopropyl group, a n-butyl group, a t-butyl group, a n-hexyl group or a cyclohexyl group, and these may be the same as or different from each other.

X represents a divalent organic group, and represents, for example, an alkylene group such as a methylene group, an ethylene group, an isopropylene group, an isobutylene group or a hexafluoroisopropylidene group, —CO—, —O—, —S—, —SO₂—, —S—S—, or an aralkylene group represented by formula (5a).

Each R⁴ independently represents a hydrogen atom or a hydrocarbon group having one or more carbon atoms, for example, a methyl group, and these may be the same as or different from each other.

Ar represents a benzene ring or a naphthalene ring, and such a benzene ring or naphthalene ring may have an alkyl group having 1 to 10 carbon atoms, an alkoxy group having 1 to 10 carbon atoms, an aryl group having 6 to 11 carbon atoms, an aralkyl group having 7 to 12 carbon atoms, an aryloxy group having 6 to 11 carbon atoms or an aralkyloxy group having 7 to 12 carbon atoms, as a substituent.

A curing agent usually used, such as a phenol resin compound, an acid anhydride compound, an amine compound, a cyanate ester compound, an active ester compound, a hydrazide compound, an acidic polyester compound or an aromatic cyanate compound, can be, if necessary, used in addition to the polyvalent hydroxy resin of the general formula (1), as the curing agent, singly or in combinations of two or more kinds thereof. When such a curing agent is used in combination, the proportion of such a curing agent used in combination in the entire curing agent is preferably 70% by mass or less, more preferably 50% by mass or less. If the proportion of such a curing agent used in combination is too high, the epoxy resin composition may have degraded dielectric properties and adhesion properties.

The molar ratio of the active hydrogen group of the curing agent per mol of the epoxy group in the entire epoxy resin, in the epoxy resin composition of the present invention, is preferably 0.2 to 1.5 mol, more preferably 0.3 to 1.4 mol, further preferably 0.5 to 1.3 mol, particularly preferably 0.8 to 1.2 mol. If the molar ratio does not fall within such a range, curing is incomplete and no favorable physical properties of a cured product may be obtained. For example, when a phenol resin-based curing agent or an amine-based curing agent is used, the active hydrogen group and the epoxy group are compounded in almost equimolar amounts. When an acid anhydride-based curing agent is used, the number of moles of the acid anhydride group compounded per mol of the epoxy group is 0.5 to 1.2 mol, preferably 0.6 to 1.0 mol. When the phenol resin of the present invention is singly used as a curing agent, the phenol resin is desirably used in the range from 0.9 to 1.1 mol per mol of the epoxy resin.

The active hydrogen group mentioned in the present invention means a functional group having active hydrogen reactive with an epoxy group (encompassing a functional group having potentially active hydrogen which generates active hydrogen by hydrolysis or the like, and a functional group exhibiting equivalent curing action.), and specific examples include an acid anhydride group, a carboxyl group, an amino group and a phenolic hydroxyl group. Herein, 1 mol of a carboxyl group or a phenolic hydroxyl group is considered to correspond to 1 mol of the active hydrogen group and 1 mol of an amino group (NH₂) is considered to correspond to 2 mol of the active hydrogen group. When the active hydrogen group is not clear, the active hydrogen equivalent can be determined by measurement. For example, the active hydrogen equivalent of a curing agent used can be determined by a reaction of a monoepoxy resin having a known epoxy equivalent, such as phenyl glycidyl ether, and a curing agent having an unknown active hydrogen equivalent and then measurement of the amount of the monoepoxy resin consumed.

Specific examples of the phenol resin-based curing agent that can be used in the epoxy resin composition of the present invention include phenol compounds mentioned as so-called novolac phenol resins, for example, bisphenol compounds such as bisphenol A, bisphenol F, bisphenol C, bisphenol K, bisphenol Z, bisphenol S, tetramethyl bisphenol A, tetramethyl bisphenol F, tetramethyl bisphenol S, tetramethyl bisphenol Z, tetrabromobisphenol A, dihydroxydiphenylsulfide and 4,4′-thiobis(3-methyl-6-t-butylphenol), dihydroxybenzene compounds such as catechol, resorcin, methylresorcin, hydroquinone, monomethylhydroquinone, dimethylhydroquinone, trimethylhydroquinone, mono-t-butylhydroquinone and di-t-butylhydroquinone, hydroxynaphthalene compounds such as dihydroxynaphthalene, dihydroxymethylnaphthalene, dihydroxymethylnaphthalene and trihydroxynaphthalene, phosphorus-containing phenol curing agents such as LC-950PM60 (manufactured by Shin-AT&C Co., Ltd.), phenol novolac resins such as Shonol BRG-555 (manufactured by Aica Kogyo Co., Ltd.), cresol novolac resins such as DC-5 (manufactured by Nippon Steel Chemical & Material Co., Ltd.), triazine backbone-containing phenol resins, aromatic modified phenol novolac resins, bisphenol A novolac resins, trishydroxyphenylmethane-type novolac resins such as Resitop TPM-100 (manufactured by Gunei Chemical Industry Co., Ltd.), condensates of phenol compounds, naphthol compounds and/or bisphenol compounds with aldehyde compounds, such as naphthol novolac resins, condensates of phenol compounds, phenol compounds and/or naphthol compounds and/or bisphenol compounds with xylylene glycols, such as SN-160, SN-395 and SN-485 (manufactured by Nippon Steel Chemical & Material Co., Ltd.), condensates of phenol compounds and/or naphthol compounds with isopropenylacetophenones, reaction products of phenol compounds and/or naphthol compounds and/or bisphenol compounds with dicyclopentadienes, reaction products of phenol compounds and/or naphthol compounds and/or bisphenol compounds with divinylbenzenes, reaction products of phenol compounds and/or naphthol compounds and/or bisphenol compounds with terpene compounds, and condensates of phenol compounds and/or naphthol compounds and/or bisphenol compounds with biphenyl-based crosslinking agents, as well as polybutadiene-modified phenol resins and phenol resins having spiro rings. A phenol novolac resin, a dicyclopentadiene phenol resin, a trishydroxyphenylmethane-type novolac resin, an aromatic modified phenol novolac resin, and the like are preferable from the viewpoint of availability.

Such a novolac phenol resin can be obtained from a phenol compound and a crosslinking agent. Examples of the phenol compound include phenol, cresol, xylenol, butylphenol, amylphenol, nonylphenol, butylmethylphenol, trimethylphenol and phenylphenol, and examples of the naphthol compound include 1-naphthol and 2-naphthol, and further include bisphenol compounds each listed as the phenol resin-based curing agent, as others. Examples of the aldehyde compound as the crosslinking agent include formaldehyde, acetaldehyde, propylaldehyde, butylaldehyde, valeraldehyde, capronaldehyde, benzaldehyde, chloroaldehyde, bromaldehyde, glyoxal, malonaldehyde, succinaldehyde, glutaraldehyde, adipinaldehyde, pimelinaldehyde, sebacinaldehyde, acrolein, crotonaldehyde, salicylaldehyde, phthalaldehyde and hydroxybenzaldehyde. Examples of the biphenyl-based crosslinking agent include bis(methylol)biphenyl, bis(methoxymethyl)biphenyl, bis(ethoxymethyl)biphenyl and bis(chloromethyl)biphenyl.

Specific examples of the acid anhydride-based curing agent include maleic anhydride, methyltetrahydrophthalic anhydride, hexahydrophthalic anhydride, 4-methylhexahydrophthalic anhydride, methylbicyclo[2.2.1]heptane-2,3-dicarboxylic anhydride, bicyclo[2.2.1]heptane-2,3-dicarboxylic anhydride, 1,2,3,6-tetrahydrophthalic anhydride, pyromellitic anhydride, phthalic anhydride, trimellitic anhydride, methylnadic acid, copolymerized products of styrene monomers and maleic anhydrides, and copolymerized products of indene compounds and maleic anhydrides.

Specific examples of the amine-based curing agent include amine-based compounds, for example, aromatic amine compounds such as diethylenetriamine, triethylenetetramine, m-xylenediamine, isophoronediamine, diaminodiphenylmethane, diaminodiphenylsulfone, diaminodiphenyl ether, benzyldimethylamine, 2,4,6-tris(dimethylaminomethyl)phenol, polyetheramine, biguanide compounds, dicyandiamide and anisidine, and polyamideamines as condensates of acid compounds such as dimer acids with polyamine compounds.

The cyanate ester compound is not particularly limited as long as it is a compound having two or more cyanate groups (cyanic acid ester groups) in one molecule. Examples include novolac-type cyanate ester-based curing agents such as phenol novolac-type and alkylphenol novolac-type curing agents, naphthol aralkyl-type cyanate ester-based curing agents, biphenylalkyl-type cyanate ester-based curing agents, dicyclopentadiene-type cyanate ester-based curing agents, bisphenol-type cyanate ester-based curing agents such as bisphenol A-type, bisphenol F-type, bisphenol E-type, tetramethyl bisphenol F-type and bisphenol S-type curing agents, and prepolymers obtained by partial triazination of such curing agents. Specific examples of such cyanate ester-based curing agents include bifunctional cyanate resins such as bisphenol A dicyanate, polyphenol cyanate (oligo(3-methylene-1,5-phenylenecyanate), bis(3-methyl-4-cyanatephenyl)methane, bis(3-ethyl-4-cyanatephenyl)methane, bis(4-cyanatephenyl)-1,1-ethane, 4,4-dicyanate-diphenyl, 2,2-bis(4-cyanatephenyl)-1,1,1,3,3,3-hexafluoropropane, 4,4′-methylenebis(2,6-dimethylphenylcyanate), 4,4′-ethylidenediphenyl dicyanate, hexafluorobisphenol A dicyanate, 2,2-bis(4-cyanate)phenylpropane, 1,1-bis(4-cyanatephenylmethane), bis(4-cyanate-3,5-dimethylphenyl)methane, 1,3-bis(4-cyanatephenyl-1-(methylethylidene))benzene, bis(4-cyanatephenyl)thio ether and bis(4-cyanatephenyl)ether, cyanic acid esters of trihydric phenols, such as tris(4-cyanatephenyl)-1,1,1-ethane and bis(3,5-dimethyl-4-cyanatephenyl)-4-cyanatephenyl-1,1,1-ethane, polyfunctional cyanate resins derived from phenol resins respectively having phenol novolac, cresol novolac, and dicyclopentadiene structures, and prepolymers obtained by partial triazination of such cyanate resins. These can be used singly or in combinations of two or more kinds thereof.

The active ester-based curing agent here used, but not particularly limited, is generally preferably a compound having two or more ester groups high in reaction activity in one molecule, such as a phenol ester compound, a thiophenol ester compound, an N-hydroxyamine ester compound, or an ester compound of a heterocyclic hydroxy compound. The active ester-based curing agent is preferably obtained by a condensation reaction of a carboxylic acid compound and/or a thiocarboxylic acid compound with a hydroxy compound and/or a thiol compound. The curing agent is preferably an active ester-based curing agent obtained from a carboxylic acid compound and a hydroxy compound, more preferably an active ester-based curing agent obtained from a carboxylic acid compound and a phenol compound and/or a naphthol compound, particularly from the viewpoint of an enhancement in heat resistance. Examples of the carboxylic acid compound include benzoic acid, acetic acid, succinic acid, maleic acid, itaconic acid, phthalic acid, isophthalic acid, terephthalic acid and pyromellitic acid. Examples of the phenol compound or the naphthol compound include hydroquinone, resorcin, bisphenol A, bisphenol F, bisphenol S, phenolphthalin, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzene triol, dicyclopentadienyl diphenol, a dicyclopentadiene phenol resin as a precursor of the epoxy resin of the present invention, and phenol novolac. Such active ester-based curing agents can be used singly or in combinations of two or more kinds thereof. The active ester-based curing agent is, specifically, preferably an active ester-based curing agent including a dicyclopentadienyl diphenol structure, an active ester-based curing agent including a naphthalene structure, an active ester-based curing agent as an acetylated product of phenol novolac, or an active ester-based curing agent as a benzoylated product of phenol novolac, in particular, more preferably an active ester-based curing agent including a dicyclopentadienyl diphenol structure, including a precursor of the epoxy resin of the present invention, from the viewpoint of an excellent enhancement in peel strength.

Specific examples of other curing agents include phosphine compounds such as triphenylphosphine, phosphonium salts such as tetraphenylphosphonium bromide, imidazole compounds such as 2-methylimidazole, 2-phenylimidazole, 2-ethyl-4-methylimidazole, 2-undecylimidazole and 1-cyanoethyl-2-methylimidazole, imidazole salt compounds as salts of imidazole compounds with trimellitic acid, isocyanuric acid or boron, quaternary ammonium salts such as trimethylammonium chloride, diazabicyclo compounds, salt compounds of diazabicyclo compounds with phenol compounds or phenol novolac resin compounds, complex compounds of boron trifluoride with amine compounds or ether compounds, aromatic phosphonium or iodonium salts.

A curing accelerator can be, if necessary, used in the epoxy resin composition. Examples of the curing accelerator that can be used include imidazole compounds such as 2-methylimidazole, 2-ethylimidazole and 2-ethyl-4-methylimidazole, tertiary amine compounds such as 4-dimethylaminopyridine, 2-(dimethylaminomethyl)phenol and 1,8-diaza-bicyclo(5,4,0)undecene-7, phosphine compounds such as triphenylphosphine, tricyclohexylphosphine and triphenylphosphine triphenylborane, and metal compounds such as tin octylate. When such a curing accelerator is used, the amount of use thereof is preferably 0.02 to 5 parts by mass based on 100 parts by mass of the epoxy resin component in the epoxy resin composition of the present invention. Such a curing accelerator can be used to thereby decrease the curing temperature and shorten the curing time.

An organic solvent or a reactive diluent for viscosity adjustment can be used in the epoxy resin composition.

Examples of the organic solvent include amide compounds such as N,N-dimethylformamide and N,N-dimethylacetamide, ether compounds such as ethylene glycol monomethyl ether, dimethoxydiethylene glycol, ethylene glycol diethyl ether, diethylene glycol diethyl ether and triethylene glycol dimethyl ether, ketone compounds such as acetone, methyl ethyl ketone, methyl isobutyl ketone and cyclohexanone, alcohol compounds such as methanol, ethanol, 1-methoxy-2-propanol, 2-ethyl-1-hexanol, benzyl alcohol, ethylene glycol, propylene glycol, butyl diglycol and pine oil, acetate compounds such as butyl acetate, methoxybutyl acetate, methyl cellosolve acetate, cellosolve acetate, ethyl diglycol acetate, propylene glycol monomethyl ether acetate, carbitol acetate and benzyl alcohol acetate, benzoate compounds such as methyl benzoate and ethyl benzoate, cellosolve compounds such as methyl cellosolve, cellosolve and butyl cellosolve, carbitol compounds such as methylcarbitol, carbitol and butylcarbitol, aromatic hydrocarbon compounds such as benzene, toluene and xylene, dimethylsulfoxide, acetonitrile, and N-methylpyrrolidone, but not limited thereto.

Examples of the reactive diluent include monofunctional glycidyl ether compounds such as allyl glycidyl ether, butyl glycidyl ether, 2-ethylhexyl glycidyl ether, phenyl glycidyl ether and tolyl glycidyl ether, and monofunctional glycidyl ester compounds such as neodecanoic acid glycidyl ester, but not limited thereto.

Such organic solvents or reactive diluents are preferably used singly or as a mixture of a plurality of kinds thereof in a non-volatile content of 90% by mass or less in the resin composition, and the proper types and amounts of use thereof are appropriately selected depending on applications. For example, a polar solvent having a boiling point of 160° C. or less, such as methyl ethyl ketone, acetone or 1-methoxy-2-propanol is preferable in a printed-wiring board application, and the amount of use thereof in the resin composition, in terms of non-volatile content, is preferably 40 to 80% by mass. For example, a ketone compound, an acetate compound, a carbitol compound, an aromatic hydrocarbon compound, dimethylformamide, dimethylacetamide or N-methylpyrrolidone is preferably used in an adhesion film application, and the amount of use thereof, in terms of non-volatile content, is preferably 30 to 60% by mass.

Any other thermosetting resin or thermoplastic resin may be compounded in the epoxy resin composition as long as no characteristics are impaired. Examples include reactive functional group-containing alkylene resins such as a phenol resin, a benzoxazine resin, a bismaleimide resin, a bismaleimide triazine resin, an acrylic resin, a petroleum resin, an indene resin, a coumarone-indene resin, a phenoxy resin, a polyurethane resin, a polyester resin, a polyamide resin, a polyimide resin, a polyamideimide resin, a polyetherimide resin, a polyphenylene ether resin, a modified polyphenylene ether resin, a polyethersulfone resin, a polysulfone resin, a polyether ether ketone resin, a polyphenylenesulfide resin, a polyvinyl formal resin, a polysiloxane compound and hydroxy group-containing polybutadiene, but not limited thereto.

Various known flame retardants can be each used in the epoxy resin composition, for the purpose of an enhancement in flame retardance of a cured product obtained. Examples of such a usable flame retardant include a halogen-based flame retardant, a phosphorus-based flame retardant, a nitrogen-based flame retardant, a silicone-based flame retardant, an inorganic flame retardant and an organic metal salt-based flame retardant. A halogen-free flame retardant is preferable and a phosphorus-based flame retardant is particularly preferable, from the viewpoint of the environment. Such flame retardants may be used singly or in combinations of two or more kinds thereof.

The phosphorus-based flame retardant here used can be any of an inorganic phosphorus-based compound and an organic phosphorus-based compound. Examples of the inorganic phosphorus-based compound include red phosphorus, ammonium phosphate compounds such as monoammonium phosphate, diammonium phosphate, triammonium phosphate and ammonium polyphosphate, and inorganic nitrogen-containing phosphorus compounds such as phosphoric amide. Examples of the organic phosphorus-based compound include aliphatic phosphate, a phosphate compound, a condensed phosphate compound such as PX-200 (manufactured by Daihachi Chemical Industry Co., Ltd.), phosphazene, a phosphonic acid compound, a phosphinic acid compound, a phosphine oxide compound, a phosphorane compound, a universal organic phosphorus-based compound such as an organic nitrogen-containing phosphorus compound, and a metal salt of phosphinic acid, as well as a cyclic organic phosphorus compound such as 9,10-dihydro-9-oxa-10-phosphaphenanthrene-10-oxide, 10-(2,5-dihydrooxyphenyl)-10H-9-oxa-10-phosphaphenanthrene-10-oxide and 10-(2,7-dihydrooxynaphthyl)-10H-9-oxa-10-phosphaphenanthrene-10-oxide, and a phosphorus-containing epoxy resin and a phosphorus-containing curing agent which are derivatives each obtained by a reaction of such a phosphorus compound with a compound such as an epoxy resin or a phenol resin.

The amount of compounding of the flame retardant is appropriately selected depending on the type of the phosphorus-based flame retardant, each component of the epoxy resin composition, and the desired degree of flame retardance. For example, the phosphorus content in the organic component (except for the organic solvent) in the epoxy resin composition is preferably 0.2 to 4% by mass, more preferably 0.4 to 3.5% by mass, further preferably 0.6 to 3% by mass. A low phosphorus content may make it difficult to ensure flame retardance, and a too high phosphorus content may have an adverse effect on heat resistance. When the phosphorus-based flame retardant is used, a flame retardant aid such as magnesium hydroxide may be used in combination.

A filler can be, if necessary, used in the epoxy resin composition. Specific examples include molten silica, crystalline silica, alumina, silicon nitride, aluminum hydroxide, boehmite, magnesium hydroxide, talc, mica, calcium carbonate, calcium silicate, calcium hydroxide, magnesium carbonate, barium carbonate, barium sulfate, boron nitride, carbon, a carbon fiber, a glass fiber, an alumina fiber, a silica/alumina fiber, a silicon carbide fiber, a polyester fiber, a cellulose fiber, an aramid fiber, a ceramic fiber, fine particle rubber, silicone rubber, a thermoplastic elastomer, carbon black and a pigment. Examples of the reason for use of the filler generally include the effect of an enhancement in impact resistance. When a metal hydroxide such as aluminum hydroxide, boehmite or magnesium hydroxide is used, it has the effect of acting as a flame retardant aid and enhancing flame retardance. The amount of compounding of such a filler is preferably 1 to 150% by mass, more preferably 10 to 70% by mass based on the entire of the epoxy resin composition. A large amount of compounding may cause deterioration in adhesiveness necessary for a laminated board application and furthermore may result in a brittle cured product and impart no sufficient mechanical properties. A small amount of compounding is liable not to have any effect by compounding of a filler, for example, an enhancement in impact resistance of a cured product.

When the epoxy resin composition is formed into a plate substrate or the like, a filler here used is preferably, for example, fibrous in terms of dimension stability and bending strength, and, for example, a glass fiber substrate where a glass fiber is woven in a net-like manner is more preferable.

Into the epoxy resin composition, various additives such as a silane coupling agent, an antioxidant, a release agent, a defoamer, an emulsifier, a thixotropy imparting agent, a lubricating agent, a flame retardant and a pigment can be further compounded, if necessary. The amount of compounding of such an additive is preferably in the range of 0.01 to 20% by mass relative to the epoxy resin composition.

A fibrous base material can be impregnated with the epoxy resin composition, to thereby produce a prepreg for use in a printed-wiring board or the like. The fibrous base material here used can be, for example, a woven fabric or a non-woven fabric of an inorganic fiber such as glass, or an organic fiber such as a polyester resin, a polyamine resin, a polyacrylic resin, a polyimide resin or an aromatic polyamide resin, but not limited thereto. The method for producing the prepreg from the epoxy resin composition is not particularly limited, and the prepreg is obtained by, for example, immersion in and impregnation with a resin varnish made by adjustment of the viscosity of the epoxy resin composition by an organic solvent, and then heating and drying for semi-curing (B-staging) of a resin component, and, for example, such heating and drying can be made at 100 to 200° C. for 1 to 40 minutes. The amount of the resin in the prepreg, in terms of resin content, is preferably 30 to 80% by mass.

The curing of the prepreg can be made by a method for curing a laminated board, generally used in production of a printed-wiring board, but not limited thereto. For example, when a laminated board is formed using the prepreg, one or more of the prepregs is/are laminated, metal foil is placed on one of or both sides of the prepregs to thereby form a laminated product, and the laminated product is heated and pressurized for lamination and integration. The metal foil here used can be any foil of a single metal, an alloy, and a composite, such as copper, aluminum, brass, and nickel. The laminated product made is then pressurized and heated to thereby cure the prepregs, and thus a laminated board can be obtained. Preferably, the heating temperature is 160 to 220° C., the pressure applied is 50 to 500 N/cm², and the heating and pressurizing time is 40 to 240 minutes, and thus an objective cured product can be obtained. A low heating temperature may cause progression of no sufficient curing reaction, and a high heating temperature may cause the start of pyrolysis of the epoxy resin composition. A low pressure applied may cause bubbles to remain in such a laminated board to result in deterioration in electric characteristics, and a high pressure applied may cause resin flowing before curing, not providing a laminated board having a desired thickness. Furthermore, a short heating and pressurizing time is not preferable because it may cause progression of no sufficient curing reaction, and a long heating and pressurizing time is not preferable because it may cause pyrolysis of the epoxy resin composition in the prepregs.

The epoxy resin composition can be cured by the same method as in a known epoxy resin composition, to obtain an epoxy resin-cured product. The method for obtaining the cured product can be the same method as in a known epoxy resin composition, and a method suitably used is, for example, a method for obtaining a laminated board by, for example, cast molding, injection, potting, dipping, drip coating, transfer molding or compression molding, or lamination of a form of, for example, a resin sheet, copper foil provided with a resin, or prepreg, and then curing with heating and pressurizing. The curing temperature is usually 100 to 300° C., and the curing time is usually about 1 hour to 5 hours.

The epoxy resin-cured product of the present invention can be in the form of, for example, a laminated product, a shaped product, an adhesion product, a coating film, or a film.

The epoxy resin composition is produced, and heated and cured, and a laminated board and a cured product are evaluated, and as a result, the cured product exhibits excellent low-dielectric properties, and furthermore an epoxy-curable resin composition excellent in copper foil peel strength and interlayer cohesion strength in a printed-wiring board application can be provided.

### EXAMPLES

The present invention is specifically described with reference to Examples and Comparative Examples, but the present invention is not limited thereto. Unless particularly noted, “parts” represents “parts by mass”, “%” represents “% by mass”, and “ppm” represents “ppm by mass”. Measurement methods were respectively the following measurement methods.

· Hydroxyl equivalent: measured in accordance with JIS K 0070 standard, where the unit was expressed by “g/eq.”. Unless particularly noted, the hydroxyl equivalent of a phenol resin means the phenolic hydroxyl equivalent.

· Softening point: measured in accordance with a ring-and-ball method in JIS K 7234 standard. Specifically, an automatic softening point apparatus (ASP-MG4 manufactured by Meitech Company, Ltd.) was used.

### Epoxy Equivalent

The epoxy equivalent was measured in accordance with JIS K 7236 standard, where the unit was expressed by “g/eq.”. Specifically, an automatic potentiometric titrator (COM-1600ST manufactured by Hiranuma Sangyo Co., Ltd.) was used, chloroform was used as a solvent, a tetraethylammonium bromide-acetic acid solution was added, and titration with a 0.1 mol/L perchloric acid-acetic acid solution was made.

### Total Content of Chlorine

The total content of chlorine was measured in accordance with JIS K 7243-3 standard, where the unit was expressed by “ppm”. Specifically, diethylene glycol monobutyl ether was used as a solvent, a 1 mol/L potassium hydroxide-1,2-propane diol solution was added and heat-treated, and thereafter titration with a 0.01 mol/L silver nitrate solution was made with an automatic potentiometric titrator (COM-1700 manufactured by Hiranuma Sangyo Co., Ltd.).

· Copper foil peel strength and interlayer adhesion force: measured in accordance with JIS C 6481. The interlayer adhesion force was measured by pulling and peeling between the seventh layer and the eighth layer.

· Relative permittivity and dielectric tangent: measured in accordance with IPC-TM-650 2.5.5.9. Specifically, evaluation was made by drying a specimen in an oven set at 105° C., for 2 hours, cooling the specimen in a desiccator, and thereafter determining the relative permittivity and the dielectric tangent at a frequency of 1 GHz by a capacitance method by use of a material analyzer manufactured by AGILENT Technologies.

### Glass Transition Temperature (Tg)

The glass transition temperature was expressed by a temperature of DSC·Tgm (intermediate temperature in a displacement curve tangent lines with respect to a glass state and a rubber state) determined in measurement in a temperature rise condition of 20° C./min with a differential scanning calorimeter (EXSTAR6000 DSC6200 manufactured by Hitachi High-Tech Science Corporation) according to IPC-TM-650 2.4.25.c.

· GPC (gel permeation chromatography) measurement: columns (TSKgelG4000H_{XL}, TSKgelG3000H_{XL} and TSKgelG2000H_{XL} manufactured by Tosoh Corporation) connected to the main body (HLC-8220 GPC manufactured by Tosoh Corporation) in series were used, and the column temperature was 40° C. The eluent here used was tetrahydrofuran (THF) at a flow rate of 1 mL/min, and the detector here used was a differential refractive index detector. The measurement specimen here used was 50 µL of one obtained by dissolving 0.1 g of a sample in 10 mL of THF and filtering the solution by a micro filter. GPC-8020 Model II version 6.00 manufactured by Tosoh Corporation was used for data processing.

· IR: the absorbance at a wavenumber of 650 to 4000 cm⁻¹ was measured with a Fourier transform infrared spectrometer (Spectrum One FT-IR Spectrometer 1760X manufactured by Perkin Elmer Precisely) and KRS-5 as a cell by coating the cell with a sample dissolved in THF and drying the resultant.

· ESI-MS: mass analysis was performed by subjecting a sample dissolved in acetonitrile to measurement with a mass spectrometer (LCMS-2020 manufactured by Shimadzu Corporation) by use of acetonitrile and water in a mobile phase.

Abbreviations used in Examples and Comparative Examples are as follows.

### Epoxy Resin

E1: Epoxy resin obtained in Example 6
E2: Epoxy resin obtained in Example 7
E3: Epoxy resin obtained in Example 8
E4: Epoxy resin obtained in Example 9
E5: Epoxy resin obtained in Example 10
HE1: Epoxy resin obtained in Synthesis Example 7

### Comparative Example 2

HE2: Phenol-dicyclopentadiene-type epoxy resin (HP-7200H manufactured by DIC Corporation, epoxy equivalent 280, softening point 83° C.)

### Curing Agent

P1: Phenol resin obtained in Example 1
P2: Phenol resin obtained in Example 2
P3: Phenol resin obtained in Example 3
P4: Phenol resin obtained in Example 4
P5: Phenol resin obtained in Example 5
A1: Phenol resin obtained in Synthesis Example 1
A2: Phenol resin obtained in Synthesis Example 2
A3: Phenol resin obtained in Synthesis Example 3
A4: Phenol resin obtained in Synthesis Example 4
A5: Phenol resin obtained in Synthesis Example 5
A6: Aromatic modified phenol resin obtained in Synthesis Example 6 (Comparative Example 1)
A7: Phenol novolac resin (Shonol BRG-557 manufactured by Aica Kogyo Co., Ltd., hydroxyl group equivalent 105, softening point 80° C.)

### Curing Accelerator

C1: 2E4MZ: 2-ethyl-4-methylimidazole (Curezol 2E4MZ manufactured by Shikoku Chemicals Corporation)

### Synthesis Example 1

A reaction apparatus including a separable flask made of glass, equipped with a stirrer, a thermometer, a nitrogen blowing tube, a dropping funnel and a cooling tube was loaded with 400 parts of o-cresol and 6.6 parts of a 47% BF₃ ether complex, and the resulting mixture was warmed to 100° C. with stirring. While this temperature was kept, 61.1 parts of dicyclopentadiene (0.12-fold moles relative to o-cresol) was dropped for 1 hour. Furthermore, the reaction was made at a temperature of 115 to 125° C. for 4 hours, and 10 parts of calcium hydroxide was added. Furthermore, 18 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. A product was dissolved by addition of 1080 parts of MIBK, and washed with water by addition of 320 parts of warm water at 80° C., and an aqueous layer as the lower layer was separated and removed. Thereafter, MIBK was evaporated and removed by warming to 160° C. under a reduced pressure of 5 mmHg, and thus 153 parts of red-brown phenol resin (A1) was obtained. The hydroxyl group equivalent was 185 and the softening point was 79° C. In GPC, the Mw was 440, the Mn was 400, the content of an m = 0 form was 0.9% by area, the content of an m = 1 form was 75.8% by area, and the content of an m ≥ 2 form was 23.3% by area.

### Synthesis Example 2

The same reaction apparatus as in Synthesis Example 1 was loaded with 360 parts of m-cresol and 5.9 parts of a 47% BF₃ ether complex, and the resulting mixture was warmed to 100° C. with stirring. While this temperature was kept, 55.0 parts of dicyclopentadiene (0.12-fold moles relative to m-cresol) was dropped for 1 hour. Furthermore, the reaction was made at a temperature of 115 to 125° C. for 4 hours, and 9 parts of calcium hydroxide was added. Furthermore, 16 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. A product was dissolved by addition of 970 parts of MIBK, and washed with water by addition of 290 parts of warm water at 80° C., and an aqueous layer as the lower layer was separated and removed. Thereafter, MIBK was evaporated and removed by warming to 160° C. under a reduced pressure of 5 mmHg, and thus 136 parts of red-brown phenol resin (A2) was obtained. The hydroxyl equivalent was 188, the softening point was 100° C. In GPC, the Mw was 450, the Mn was 420, the content of an m = 0 form was 0.5% by area, the content of an m = 1 form was 76.5% by area, and the content of an m ≥ 2 form was 22.9% by area.

### Synthesis Example 3

The same reaction apparatus as in Synthesis Example 1 was loaded with 500 parts of 2,6-xylenol and 7.3 parts of a 47% BF₃ ether complex, and the resulting mixture was warmed to 100° C. with stirring. While this temperature was kept, 67.6 parts of dicyclopentadiene (0.12-fold moles relative to 2,6-xylenol) was dropped for 1 hour. Furthermore, the reaction was made at a temperature of 115 to 125° C. for 4 hours, and 11 parts of calcium hydroxide was added. Furthermore, 19 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. A product was dissolved by addition of 1320 parts of MIBK, and washed with water by addition of 400 parts of warm water at 80° C., and an aqueous layer as the lower layer was separated and removed. Thereafter, MIBK was evaporated and removed by warming to 160° C. under a reduced pressure of 5 mmHg, and thus 164 parts of red-brown phenol resin (A3) was obtained. The hydroxyl group equivalent was 195 and the softening point was 73° C. In GPC, the Mw was 470, the Mn was 440, the content of an m = 0 form was 2.8% by area, the content of an m = 1 form was 86.2% by area, and the content of an m ≥ 2 form was 11.0% by area.

### Synthesis Example 4

The same reaction apparatus as in Synthesis Example 1 was loaded with 360 parts of 2,5-xylenol and 5.2 parts of a 47% BF₃ ether complex, and the resulting mixture was warmed to 100° C. with stirring. While this temperature was kept, 48.7 parts of dicyclopentadiene (0.12-fold moles relative to 2,5-xylenol) was dropped for 1 hour. Furthermore, the reaction was made at a temperature of 115 to 125° C. for 4 hours, and 8 parts of calcium hydroxide was added. Furthermore, 14 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. A product was dissolved by addition of 950 parts of MIBK, and washed with water by addition of 290 parts of warm water at 80° C., and an aqueous layer as the lower layer was separated and removed. Thereafter, MIBK was evaporated and removed by warming to 160° C. under a reduced pressure of 5 mmHg, and thus 130 parts of red-brown phenol resin (A4) was obtained. The hydroxyl group equivalent was 206 and the softening point was 108° C. In GPC, the Mw was 450, the Mn was 420, the content of an m = 0 form was 2.6% by area, the content of an m = 1 form was 84.6% by area, and the content of an m ≥ 2 form was 12.9% by area.

### Synthesis Example 5

The same reaction apparatus as in Synthesis Example 1 was loaded with 400 parts of phenol and 7.5 parts of a 47% BF₃ ether complex, and the resulting mixture was warmed to 100° C. with stirring. While this temperature was kept, 70.2 parts of dicyclopentadiene (0.12-fold moles relative to phenol) was dropped for 1 hour. Furthermore, the reaction was made at a temperature of 115 to 125° C. for 4 hours, and 12 parts of calcium hydroxide was added. Furthermore, 20 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. A product was dissolved by addition of 1100 parts of MIBK, and washed with water by addition of 330 parts of warm water at 80° C., and an aqueous layer as the lower layer was separated and removed. Thereafter, MIBK was evaporated and removed by warming to 160° C. under a reduced pressure of 5 mmHg, and thus 110 parts of brown phenol resin (A5) was obtained. The hydroxyl group equivalent was 177 and the softening point was 92° C. In GPC, the Mw was 460, the Mn was 390, the content of an m = 0 form was 0% by area, the content of an m = 1 form was 66.7% by area, and the content of an m ≥ 2 form was 33.3% by area.

### Synthesis Example 6 (Comparative Example 1)

The same reaction apparatus as in Synthesis Example 1 was loaded with 105 parts of a phenol novolac resin (hydroxyl group equivalent 105, softening point 130° C.) and 0.1 parts of p-toluenesulfonic acid, and the temperature was raised to 150° C. While this temperature was maintained, 94 parts of styrene was dropped for 3 hours, and furthermore stirring was continued at this temperature for 1 hour. Thereafter, the resultant was dissolved in 500 parts of MIBK, and washed with water at 80° C. five times. Subsequently, MIBK was distilled off under reduced pressure, and thus aromatic modified phenol novolac resin (A6) was obtained. The hydroxyl group equivalent was 199 and the softening point was 110° C.

### Example · BR > P

The same reaction apparatus as in Synthesis Example 1 was loaded with 121 parts of phenol resin (A1) obtained in Synthesis Example 1, 1.2 parts of a 47% BF₃ ether complex and 30 parts of MIBK, and the resulting mixture was warmed to 100° C. with stirring. While this temperature was kept, 36.3 parts of dicyclopentadiene (0.42-fold moles relative to phenol resin) was dropped for 1 hour. Furthermore, the reaction was made at a temperature of 115 to 125° C. for 4 hours, and 2 parts of calcium hydroxide was added. Furthermore, 3 parts of an aqueous 10% oxalic acid solution was added. Thereafter, the resultant was warmed to 160° C. for dehydration, and thereafter warmed to 200° C. under a reduced pressure of 5 mmHg. A product was dissolved by addition of 340 parts of MIBK, and washed with water by addition of 110 parts of warm water at 80° C., and an aqueous layer as the lower layer was separated and removed. Thereafter, MIBK was evaporated and removed by warming to 160° C. under a reduced pressure of 5 mmHg, and thus 155 parts of red-brown phenol resin (A6) was obtained. The hydroxyl group equivalent was 259, the softening point was 106° C., and the absorption ratio (A₃₀₄₀/A₁₂₁₀) was 0.19. A mass spectrum by ESI-MS (negative) was measured, and the following was confirmed: M- = 347, 479, 587, 719. A GPC chart and an IR chart of phenol resin (P1) obtained are respectively illustrated in FIG. 1 and FIG. 2. In GPC, the Mw was 690, the Mn was 530, the content of an n = 0 form was 0.7% by area, the content of an n = 1 form was 52.6% by area, and the content of an n ≥ 2 form was 46.6% by area.

### Example 2

The same reaction apparatus as in Synthesis Example 1 was loaded with 101 parts of phenol resin (A2) obtained in Synthesis Example 2, 1.0 part of a 47% BF₃ ether complex and 25 parts of MIBK, and the resulting mixture was warmed to 100° C. with stirring. While this temperature was kept, 30.2 parts of dicyclopentadiene (0.42-fold moles relative to phenol resin) was dropped for 1 hour. Furthermore, the reaction was made at a temperature of 115 to 125° C. for 4 hours, and 2 parts of calcium hydroxide was added. Furthermore, 3 parts of an aqueous 10% oxalic acid solution was added. Thereafter, the resultant was warmed to 160° C. for dehydration, and thereafter warmed to 200° C. under a reduced pressure of 5 mmHg. A product was dissolved by addition of 280 parts of MIBK, and washed with water by addition of 90 parts of warm water at 80° C., and an aqueous layer as the lower layer was separated and removed. Thereafter, MIBK was evaporated and removed by warming to 160° C. under a reduced pressure of 5 mmHg, and thus 125 parts of red-brown phenol resin (P2) was obtained. The hydroxyl group equivalent was 309, the softening point was 152° C., and the absorption ratio (A₃₀₄₀/A₁₂₁₀) was 0.20. A mass spectrum by ESI-MS (negative) was measured, and the following was confirmed: M- = 347, 479, 587, 719. In GPC, the Mw was 1240, the Mn was 710, the content of an n = 0 form was 1.0% by area, the content of an n = 1 form was 33.3% by area, and the content of an n ≥ 2 form was 65.7% by area.

### Example 3

The same reaction apparatus as in Synthesis Example 1 was loaded with 352 parts of phenol resin (A3) obtained in Synthesis Example 3, 3.5 parts of a 47% BF₃ ether complex and 88 parts of MIBK, and the resulting mixture was warmed to 100° C. with stirring. While this temperature was kept, 105.7 parts of dicyclopentadiene (0.44-fold moles relative to phenol resin) was dropped for 1 hour. Furthermore, the reaction was made at a temperature of 115 to 125° C. for 4 hours, and 6 parts of calcium hydroxide was added. Furthermore, 9 parts of an aqueous 10% oxalic acid solution was added. Thereafter, the resultant was warmed to 160° C. for dehydration, and thereafter warmed to 200° C. under a reduced pressure of 5 mmHg. A product was dissolved by addition of 980 parts of MIBK, and washed with water by addition of 320 parts of warm water at 80° C., and an aqueous layer as the lower layer was separated and removed. Thereafter, MIBK was evaporated and removed by warming to 160° C. under a reduced pressure of 5 mmHg, and thus 444 parts of red-brown phenol resin (P3) was obtained. The hydroxyl group equivalent was 275, the softening point was 96° C., and the absorption ratio (A₃₀₄₀/A₁₂₁₀) was 0.19. A mass spectrum by ESI-MS (negative) was measured, and the following was confirmed: M- = 375, 507, 629, 761. In GPC, the Mw was 720, the Mn was 530, the content of an n = 0 form was 6.9% by area, the content of an n = 1 form was 64.9% by area, and the content of an n ≥ 2 form was 28.2% by area.

### Example 4

The same reaction apparatus as in Synthesis Example 1 was loaded with 101 parts of phenol resin (A4) obtained in Synthesis Example 4, 1.0 part of a 47% BF₃ ether complex and 25 parts of MIBK, and the resulting mixture was warmed to 100° C. with stirring. While this temperature was kept, 30.2 parts of dicyclopentadiene (0.44-fold moles relative to phenol resin) was dropped for 1 hour. Furthermore, the reaction was made at a temperature of 115 to 125° C. for 4 hours, and 2 parts of calcium hydroxide was added. Furthermore, 3 parts of an aqueous 10% oxalic acid solution was added. Thereafter, the resultant was warmed to 160° C. for dehydration, and thereafter warmed to 200° C. under a reduced pressure of 5 mmHg. A product was dissolved by addition of 280 parts of MIBK, and washed with water by addition of 90 parts of warm water at 80° C., and an aqueous layer as the lower layer was separated and removed. Thereafter, MIBK was evaporated and removed by warming to 160° C. under a reduced pressure of 5 mmHg, and thus 127 parts of red-brown phenol resin (P4) was obtained. The hydroxyl group equivalent was 355, the softening point was 141° C., and the absorption ratio (A₃₀₄₀/A₁₂₁₀) was 0.20. A mass spectrum by ESI-MS (negative) was measured, and the following was confirmed: M- = 375, 507, 629, 761. In GPC, the Mw was 790, the Mn was 570, the content of an n = 0 form was 5.1% by area, the content of an n = 1 form was 58.8% by area, and the content of an n ≥ 2 form was 36.1% by area.

### Example 5

The same reaction apparatus as in Synthesis Example 1 was loaded with 100 parts of phenol resin (A5) obtained in Synthesis Example 5, 1.0 part of a 47% BF₃ ether complex and 25 parts of MIBK, and the resulting mixture was warmed to 100° C. with stirring. While this temperature was kept, 30.0 parts of dicyclopentadiene (0.40-fold moles relative to phenol resin) was dropped for 1 hour. Furthermore, the reaction was made at a temperature of 115 to 125° C. for 4 hours, and 2 parts of calcium hydroxide was added. Furthermore, 3 parts of an aqueous 10% oxalic acid solution was added. Thereafter, the resultant was warmed to 160° C. for dehydration, and thereafter warmed to 200° C. under a reduced pressure of 5 mmHg. A product was dissolved by addition of 280 parts of MIBK, and washed with water by addition of 90 parts of warm water at 80° C., and an aqueous layer as the lower layer was separated and removed. Thereafter, MIBK was evaporated and removed by warming to 160° C. under a reduced pressure of 5 mmHg, and thus 126 parts of red-brown phenol resin (P5) was obtained. The hydroxyl group equivalent was 287, the softening point was 150° C., and the absorption ratio (A₃₀₄₀/A₁₂₁₀) was 0.23. A mass spectrum by ESI-MS (negative) was measured, and the following was confirmed: M- = 319, 451, 545, 677. In GPC, the Mw was 1390, the Mn was 760, the content of an n = 0 form was 0.5% by area, the content of an n = 1 form was 23.0% by area, and the content of an n ≥ 2 form was 76.5% by area.

### Example 6

To a reaction apparatus equipped with a stirrer, a thermometer, a nitrogen blowing tube, a dropping funnel and a cooling tube were added 139 parts of phenol resin (P1) obtained in Example 1, 247 parts of epichlorohydrin and 74 parts of diethylene glycol dimethyl ether, and the resulting mixture was warmed to 65° C. While the temperature was kept at 63 to 67° C. under a reduced pressure of 125 mmHg, 48.0 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 390 parts of MIBK was added to dissolve a product. Thereafter, 120 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 159 parts of red-brown dicyclopentadiene-type epoxy resin (E1) was obtained. The resin had an epoxy equivalent of 328, a total content of chlorine of 950 ppm, and a softening point of 82° C. A GPC chart and an IR chart of epoxy resin (E1) obtained are respectively illustrated in FIG. 3 and FIG. 4. In GPC, the Mw was 780, the Mn was 560, the content of a k = 0 form was 1.3% by area, the content of a k = 1 form was 49.7% by area, and the content of a k ≥ 2 form was 49.0% by area.

### Example 7

To the same reaction apparatus as in Example 6 were added 100 parts of phenol resin (P2) obtained Example 2, 150 parts of epichlorohydrin and 45 parts of diethylene glycol dimethyl ether, and the resulting mixture was warmed to 65° C. While the temperature was kept at 63 to 67° C. under a reduced pressure of 125 mmHg, 29.1 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 280 parts of MIBK was added to dissolve a product. Thereafter, 80 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 109 parts of red-brown dicyclopentadiene-type epoxy resin (E2) was obtained. The resin had an epoxy equivalent of 382, a total content of chlorine of 1180 ppm, and a softening point of 130° C. In GPC, the Mw was 1460, the Mn was 760, the content of a k = 0 form was 0.7% by area, the content of a k = 1 form was 31.0% by area, and the content of a k ≥ 2 form was 68.3% by area.

### Example 8

To the same reaction apparatus as in Example 6 were added 370 parts of phenol resin (P3) obtained in Example 3, 622 parts of epichlorohydrin and 187 parts of diethylene glycol dimethyl ether, and the resulting mixture was warmed to 65° C. While the temperature was kept at 63 to 67° C. under a reduced pressure of 125 mmHg, 120.7 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 1040 parts of MIBK was added to dissolve a product. Thereafter, 310 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 425 parts of red-brown dicyclopentadiene-type epoxy resin (E3) was obtained. The resin had an epoxy equivalent of 358, a total content of chlorine of 520 ppm, and a softening point of 80° C. In GPC, the Mw was 870, the Mn was 570, the content of a k = 0 form was 5.5% by area, the content of a k = 1 form was 61.8% by area, and the content of a k ≥ 2 form was 32.6% by area.

### Example 9

To the same reaction apparatus as in Example 6 were added 101 parts of phenol resin (P4) obtained in Example 4, 131 parts of epichlorohydrin and 39 parts of diethylene glycol dimethyl ether, and the resulting mixture was warmed to 65° C. While the temperature was kept at 63 to 67° C. under a reduced pressure of 125 mmHg, 25.5 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 270 parts of MIBK was added to dissolve a product. Thereafter, 80 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 112 parts of red-brown dicyclopentadiene-type epoxy resin (E4) was obtained. The resin had an epoxy equivalent of 429, a total content of chlorine of 540 ppm, and a softening point of 125° C. In GPC, the Mw was 1010, the Mn was 630, the content of a k = 0 form was 4.3% by area, the content of a k = 1 form was 49.9% by area, and the content of a k ≥ 2 form was 45.8% by area.

### Example 10

To the same reaction apparatus as in Example 6 were added 102 parts of phenol resin (P5) obtained in Example 5, 165 parts of epichlorohydrin and 49 parts of diethylene glycol dimethyl ether, and the resulting mixture was warmed to 65° C. While the temperature was kept at 63 to 67° C. under a reduced pressure of 125 mmHg, 32.0 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 290 parts of MIBK was added to dissolve a product. Thereafter, 90 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 97 parts of red-brown dicyclopentadiene-type epoxy resin (E5) was obtained. The resin had an epoxy equivalent of 382, a total content of chlorine of 560 ppm, and a softening point of 132° C. In GPC, the Mw was 2960, the Mn was 920, the content of a k = 0 form was 0.6% by area, the content of a k = 1 form was 19.4%, and the content of a k ≥ 2 form was 80.0%.

### Synthesis Example 7 (Comparative Example 2)

To the same reaction apparatus as in Example 6 were added 150 parts of phenol resin (A3) obtained in Synthesis Example 3, 356 parts of epichlorohydrin and 107 parts of diethylene glycol dimethyl ether, and the resulting mixture was warmed to 65° C. While the temperature was kept at 63 to 67° C. under a reduced pressure of 125 mmHg, 69.1 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 450 parts of MIBK was added to dissolve a product. Thereafter, 140 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 183 parts of red-brown dicyclopentadiene-type epoxy resin (HE1) was obtained. The resin had an epoxy equivalent of 261, a total content of chlorine of 710 ppm, and a softening point of 55° C. In GPC, the Mw was 670, the Mn was 570, the content of a k = 0 form was 2.3% by area, the content of a k = 1 form was 73.1% by area, and the content of a k ≥ 2 form was 24.6% by area.

### Example 11

One hundred parts of epoxy resin (E1) as an epoxy resin, 32 parts of phenol resin (A7) as a curing agent, and 0.20 parts of C1 as a curing accelerator were compounded, and dissolved in a mixed solvent adjusted from MEK, propylene glycol monomethyl ether and N,N-dimethylformamide, to thereby obtain an epoxy resin composition varnish. A glass cloth (WEA 7628 XS13 manufactured by Nitto Boseki Co., Ltd., 0.18 mm in thickness) was impregnated with the epoxy resin composition varnish obtained. The glass cloth impregnated was dried in a hot air oven at 150° C. for 9 minutes, to thereby obtain a prepreg. Eight of the prepregs obtained and copper foil (3EC-III manufactured by Mitsui Mining & Smelting Co., Ltd., thickness 35 µm) were stacked with the copper foil being located on and below the prepregs, and the resulting stacked product was pressed in vacuum at 2 MPa in temperature conditions of 130° C. x 15 minutes + 190° C. x 80 minutes, to thereby obtain a laminated board having a thickness of 1.6 mm. The results of the copper foil peel strength and interlayer adhesion force of the laminated board are shown in Table 1.

The prepregs obtained were ground, to thereby provide a ground prepreg powder by passing through a 100-mesh sieve. The prepreg powder obtained was placed into a fluororesin mold, and pressed in vacuum at 2 MPa in temperature conditions of 130° C. x 15 minutes + 190° C. x 80 minutes, to thereby obtain a test piece of 50 mm square x 2 mm thickness. The results of the relative permittivity and dielectric tangent in the test piece are shown in Table 1.

### Examples 12 to 36 and Comparative Examples 11 To 20

Each laminated board and each test piece were obtained by compounding at each amount of compounding (part(s)) in Tables 1 to 4 and by the same operations performed as in Example 11. The curing accelerator was used in an amount so that the varnish gelation time could be adjusted to about 300 seconds. The same test as in Example 11 was performed. The results are shown in Tables 1 to 4.

TABLE 1

| | Example 11 | Example 12 | Example 13 | Example 14 | Example 15 | Comparative Example 11 | Comparative Example 12 |
|---|---|---|---|---|---|---|---|
| E1 | 100 | | | | | | |
| E2 | | 100 | | | | | |
| E3 | | | 100 | | | | |
| E4 | | | | 100 | | | |
| E5 | | | | | 100 | | |
| HE1 | | | | | | 100 | |
| HE2 | | | | | | | 100 |
| A7 | 32 | 32 | 29 | 29 | 29 | 40 | 38 |
| C1 | 0.20 | 0.15 | 0.30 | 0.25 | 0.15 | 0.20 | 0.10 |
| Copper foil peel strength (kN/m) | 1.3 | 1.3 | 1.4 | 1.3 | 1.3 | 1.7 | 1.6 |
| Interlayer adhesion force (kN/m) | 1.1 | 1.1 | 1.2 | 1.2 | 1.1 | 1.4 | 1.2 |
| Relative permittivity | 2.89 | 2.93 | 2.90 | 2.91 | 2.95 | 3.01 | 3.17 |
| Dielectric tangent | 0.014 | 0.014 | 0.013 | 0.013 | 0.016 | 0.015 | 0.021 |
| Tg (°C) | 171 | 172 | 168 | 169 | 175 | 174 | 184 |

TABLE 2

| | Example 16 | Example 17 | Example 18 | Example 19 | Example 20 | Comparative Example 13 | Comparative Example 14 |
|---|---|---|---|---|---|---|---|
| E3 | 100 | 100 | 100 | | | | |
| HE2 | | | | 100 | 100 | 100 | 100 |
| P3 | 38 | 38 | 38 | 98 | 49 | | |
| A3 | 27 | | | | | 70 | |
| A5 | | 25 | | | | | 63 |
| A7 | | | 15 | | 19 | | |
| C1 | 0.40 | 0.38 | 0.36 | 0.25 | 0.20 | 0.22 | 0.17 |
| Copper foil peel strength (kN/m) | 1.4 | 1.3 | 1.3 | 1.4 | 1.4 | 1.7 | 1.6 |
| Interlayer adhesion force (kN/m) | 1.3 | 1.1 | 1.1 | 1.1 | 1.1 | 1.4 | 1.2 |
| Relative permittivity | 2.71 | 2.75 | 2.78 | 2.89 | 2.90 | 3.03 | 3.07 |
| Dielectric tangent | 0.009 | 0.010 | 0.011 | 0.013 | 0.013 | 0.016 | 0.020 |
| Tg (°C) | 156 | 158 | 165 | 175 | 171 | 158 | 168 |

TABLE 3

| | Example 21 | Example 22 | Example 23 | Example 24 | Example 25 | Comparative Example 15 | Comparative Example 16 | Comparative Example 17 | Comparative Example 18 | Comparative Example 19 | Comparative Example 20 |
|---|---|---|---|---|---|---|---|---|---|---|---|
| HE1 | 100 | 100 | 100 | 100 | 100 | 100 | 100 | 100 | 100 | 100 | 100 |
| P1 | 99 | | | | | | | | | | |
| P2 | | 119 | | | | | | | | | |
| P3 | | | 106 | | | | | | | | |
| P4 | | | | 136 | | | | | | | |
| P5 | | | | | 110 | | | | | | |
| A1 | | | | | | 71 | | | | | |
| A2 | | | | | | | 71 | | | | |
| A3 | | | | | | | | 75 | | | |
| A4 | | | | | | | | | 75 | | |
| A5 | | | | | | | | | | 68 | |
| A6 | | | | | | | | | | | 76 |
| C1 | 0.38 | 0.38 | 0.42 | 0.42 | 0.28 | 0.35 | 0.35 | 0.40 | 0.40 | 0.30 | 0.52 |
| Copper foil peel strength (kN/m) | 1.3 | 1.3 | 1.5 | 1.5 | 1.4 | 1.6 | 1.6 | 1.8 | 1.8 | 1.7 | 1.6 |
| Interlayer adhesion force (kN/m) | 1.1 | 1.1 | 1.3 | 1.1 | 1.2 | 1.4 | 1.4 | 1.6 | 1.5 | 1.4 | 0.8 |
| Relative permittivity | 2.85 | 2.89 | 2.80 | 2.83 | 2.86 | 2.94 | 2.97 | 2.88 | 2.93 | 2.93 | 2.93 |
| Dielectric tangent | 0.012 | 0.013 | 0.011 | 0.012 | 0.013 | 0.013 | 0.014 | 0.012 | 0.014 | 0.015 | 0.012 |
| Tg (°C) | 164 | 165 | 162 | 165 | 167 | 152 | 154 | 149 | 152 | 157 | 161 |

TABLE 4

| | Example 26 | Example 27 | Example 28 | Example 29 | Example 30 | Example 31 | Example 32 | Example 33 | Example 34 | Example 35 | Example 36 |
|---|---|---|---|---|---|---|---|---|---|---|---|
| E3 | 100 | 100 | 100 | 100 | 100 | 100 | 100 | 100 | 100 | 100 | 100 |
| P1 | 72 | | | | | | | | | | |
| P2 | | 73 | | | | | | | | | |
| P3 | | | 77 | | | | | | | | |
| P4 | | | | 76 | | | | | | | |
| P5 | | | | | 80 | | | | | | |
| A1 | | | | | | 52 | | | | | |
| A2 | | | | | | | 52 | | | | |
| A3 | | | | | | | | 54 | | | |
| A4 | | | | | | | | | 54 | | |
| A5 | | | | | | | | | | 49 | |
| A6 | | | | | | | | | | | 56 |
| C1 | 0.38 | 0.38 | 0.40 | 0.40 | 0.30 | 0.35 | 0.35 | 0.38 | 0.38 | 0.34 | 0.60 |
| Copper foil peel strength (kN/m) | 1.1 | 1.1 | 1.2 | 1.2 | 1.0 | 1.4 | 1.4 | 1.5 | 1.5 | 1.4 | 1.2 |
| Interlayer adhesion force (kN/m) | 1.0 | 1.0 | 1.1 | 1.0 | 0.9 | 1.3 | 1.3 | 1.4 | 1.4 | 1.2 | 0.7 |
| Relative permittivity | 2.71 | 2.74 | 2.65 | 2.68 | 2.80 | 2.80 | 2.83 | 2.75 | 2.78 | 2.81 | 2.81 |
| Dielectric tangent | 0.009 | 0.010 | 0.008 | 0.009 | 0.011 | 0.010 | 0.011 | 0.009 | 0.010 | 0.012 | 0.011 |
| Tg (°C) | 162 | 163 | 160 | 162 | 165 | 151 | 153 | 148 | 150 | 155 | 163 |

As is clear from the results, each of the dicyclopentenyl group-containing dicyclopentadiene-type epoxy resins and each of the dicyclopentenyl group-containing dicyclopentadiene-type phenol resins obtained in Examples, and a resin composition including such each resin can provide a resin-cured product that exhibits very favorable low dielectric properties and furthermore that is also excellent in adhesion force.

The phenol resin of the present invention can be used variously in paints, civil adhesion, cast molding, electrical and electronic materials, film materials, and the like, and is useful particularly in a printed-wiring substrate application.

1. A phenol resin containing a dicyclopentenyl group and represented by the following general formula (1): 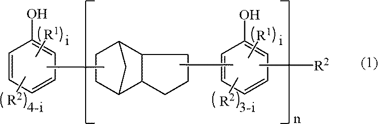
wherein each R¹ independently represents a hydrocarbon group having 1 to 8 carbon atoms; each R² independently represents a hydrogen atom or a dicyclopentenyl group, and at least one R² is a dicyclopentenyl group; i is an integer of 0 to 2; and n represents the number of repetitions and an average value thereof is a number of 0 to 10.

2. The phenol resin according to claim 1, wherein R¹ is a methyl group or a phenyl group, and i is 1 or 2.

3. A method for producing the phenol resin according to claim 1, comprising reacting 0.05 to 2.0 mol of dicyclopentadiene per mol of a phenolic hydroxyl group of a phenol resin represented by the following general formula (3) at a reaction temperature of 50 to 200° C., in the presence of a Lewis acid: 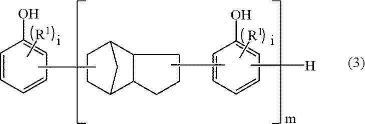
wherein each R¹ independently represents a hydrocarbon group having 1 to 8 carbon atoms; i is an integer of 0 to 2; and m represents the number of repetitions and an average value thereof is a number of 0 to 5.

4. The method for producing the phenol resin according to claim 3, wherein 0.001 to 20 parts by mass of a Lewis acid based on 100 parts by mass of the dicyclopentadiene is used.

5. An epoxy resin containing a dicyclopentenyl group and represented by the following general formula (2): 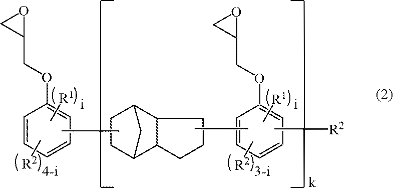
wherein each R¹ independently represents a hydrocarbon group having 1 to 8 carbon atoms; each R² independently represents a hydrogen atom or a dicyclopentenyl group, and at least one R² is a dicyclopentenyl group; i is an integer of 0 to 2; and k represents the number of repetitions and an average value thereof is a number of 0 to 10.

6. A method for producing the epoxy resin according to claim 5, comprising reacting 1 to 20 mol of epihalohydrin per mol of a phenolic hydroxyl group of a phenol resin containing a dicyclopentenyl group and represented by the following general formula (1), in the presence of an alkali metal hydroxide: 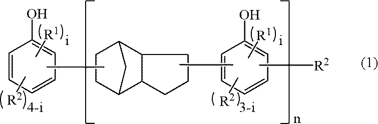
wherein each R¹ independently represents a hydrocarbon group having 1 to 8 carbon atoms; each R² independently represents a hydrogen atom or a dicyclopentenyl group, and at least one R² is a dicyclopentenyl group, i is an integer of 0 to 2; and n represents the number of repetitions and an average value thereof is a number of 0 to 10.

7. An epoxy resin composition comprising an epoxy resin and a curing agent, wherein the curing agent is partially or fully the phenol resin according to claim 1.

8. An epoxy resin composition comprising an epoxy resin and a curing agent, wherein the epoxy resin is partially or fully the epoxy resin according to claim 5.

9. An epoxy resin composition comprising an epoxy resin and a curing agent, wherein the curing agent is partially or fully the phenol resin according to claim 1, and the epoxy resin is partially or fully a epoxy resin containing a dicyclopentenyl group and represented by the following general formula (2): 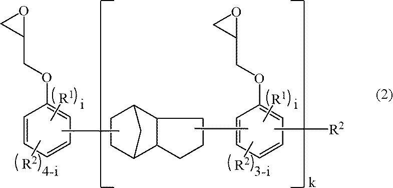
wherein each R¹ independently represents a hydrocarbon group having 1 to 8 carbon atoms; each R² independently represents a hydrogen atom or a dicyclopentenyl group, and at least one R² is a dicyclopentenyl group; i is an integer of 0 to 2; and k represents the number of repetitions and an average value thereof is a number of 0 to 10.

10. A prepreg using the epoxy resin composition according to claim 7.

11. A laminated board using the epoxy resin composition according to claim 7.

12. A printed-wiring substrate using the epoxy resin composition according to claim 7.

13. A cured product obtained by curing the epoxy resin composition according to claim 7.

14. A prepreg using the epoxy resin composition according to claim 8.

15. A prepreg using the epoxy resin composition according to claim 9.

16. A laminated board using the epoxy resin composition according to claim 8.

17. A laminated board using the epoxy resin composition according to claim 9.

18. A printed-wiring substrate using the epoxy resin composition according to claim 8.

19. A printed-wiring substrate using the epoxy resin composition according to claim 9.

20. A cured product obtained by curing the epoxy resin composition according to claim 8.

21. A cured product obtained by curing the epoxy resin composition according to claim 9.
